(19) United States
(12) Patent Application Publication
(10) Pub. No.: US 2009/0020069 A1
(43) Pub. Date: Jan. 22, 2009

(54) Multi-Beam Optical Afterheater for Laser Heated Pedestal Growth

(76) Inventors: Eugene Standifer, Menlo Park, CA (US); Gisele Maxwell, Palo Alto, CA (US)

Correspondence Address: FENWICK & WEST LLP, SILICON VALLEY CENTER, 801 CALIFORNIA STREET, MOUNTAIN VIEW, CA, 94041, US

(21) Appl. No.: 12/020,382

(22) Filed: Jan. 25, 2008

Related U.S. Application Data
(60) Provisional application No. 60/886,886, filed on Jan. 26, 2007.

(51) Int. Cl. C30B 13/24

(52) U.S. Cl. 117/204

(57) ABSTRACT

A post-growth optical afterheater system includes an appropriate choice of optical heat source for the single crystal material to be heated, a power adjustment module for controlling the optical power heating the crystal, and suitable focusing optics to focus the heating beam onto the crystal. The heat source may be a laser of appropriate wavelength or an incoherent source of sufficient power. In one embodiment, the power adjustment module is an optical attenuator, either of crossed-polarizer design or of intersecting wire grids. The focusing optics may be refractive, reflective, or catadioptric, depending on factors such as diameter, cost target, and space available in the crystal growth apparatus.

### CROSS-REFERENCE TO RELATED APPLICATION(S)

This application claims priority under 35 U.S.C. § 119(e) to U.S. Provisional Patent Application Ser. No. 60/886,886, “Multi-Beam Optical Afterheater For Laser Heated Pedestal Growth,” filed Jan. 26, 2007. The subject matter of the foregoing is incorporated herein by reference in its entirety.

### BACKGROUND OF THE INVENTION

1. Field of the Invention

This invention relates generally to laser heated pedestal growth (LHPG) of crystals and, more particularly, to LHPG utilizing an optical afterheater.

2. Description of the Related Art

Laser-Heated Pedestal Growth (or “LHPG”) is a versatile technique for growing small single crystalline fibers of many refractory materials. The many crystal growth studies employing LHPG have been reviewed by Feigelson [Mat. Sci. Engin. B1 (1988) 67], and updated by Yen [W. M. Yen. in: Insulating Materials for Optoelectronics: New Developments; F. Agullo-Lopez, ed. (1995), Ch. 2] and by Rudolph & Fukuda [Rudolph, P.; Fukuda, T.: Cryst. Res. Technol. 34 (1999) 3]. The basics of the LHPG system are described in U.S. Pat. No. 4,421,721, which is incorporated herein by reference. This system has enabled the growth of fiber crystals by many research groups around the world. Fiber crystals typically have dimensions ranging from a few microns up to one millimeter in diameter, and lengths up to several meters. This nearly one-dimensional geometry implies that the fiber crystal is free of any linear or planar defects which do not lie along the growth axis. Due primarily to interest in the unusual properties of such low dislocation density crystals, investigators have grown and characterized a wide array of single crystalline fibers, with applications such as optical waveguides, laser gain media, nonlinear optics, and many other fields.

Several practical advantages of the LHPG system as described in U.S. Pat. No. 4,421,721 make it well-suited for growth of crystalline materials in an industrial setting. The absence of a container eliminates the expense of a precious metal crucible (e.g., Pt, Rh, Ir) needed in many alternative crystal growth methods. The efficient use of material (especially for nonvolatile melt compositions) reduces waste of expensive source compounds. The high crystal pull rates enabled by the large axial thermal gradient allow faster growth of usable crystalline fibers than other growth methods. Finally, the rod geometry satisfies the requirements of applications ranging from fiber lasers to optical waveguides, reducing the need for expensive post-growth grinding and polishing processes.

In the LHPG technique, the top of a source rod having the composition of the material to be grown is melted using a laser such as a power-stabilized CO₂ continuous wave (CW) laser as the heating source. The single crystal fiber is pulled up from this molten zone. Since the laser beam is typically fixed in space, the source rod is continuously moved into the beam as the fiber grows so as to preserve melt volume. No crucible is necessary. While a chamber surrounding the growth zone is sometimes desirable to allow the use of reactive or inert gases, no hot furnace parts, which can lead to contamination of the melt, are involved.

For many spectroscopic or optoelectronic applications, the diameter of the fibers can generally be a few hundred microns, and in such cases the power of the CO₂ CW laser utilized for LHPG will normally be in the 10-50 W range (depending primarily on the material's melting point, and secondarily on its diameter and thermal conductivity). A laser beam is focused on the source rod after the beam has passed through an appropriate set of turning and focusing optics. The laser radiation is absorbed, producing a self supporting molten bead at the tip of the source rod. An appropriate seed crystal is then dipped into the melt, and crystallization occurs at the seed/melt interface as the seed is pulled upwards out of the melt and away from exposure to the heating laser beam. Surface tension of the molten bead holds the seed and the melt together and is responsible for forming the pedestal shape of the melt under the dynamics of pulling. As material is fed into the crystallizing fiber, the source rod is simultaneously fed into the heating zone in order to maintain a constant volume of melt. The diameter of the resulting fiber is determined by the ratio of the fiber pulling speed to source feeding speed. Although it is conventional to refer to the crystal (which is conventionally referred to as a “fiber” in the small diameters accessible to the prior art) as being pulled “upwards” from the melt, it is to be understood that the apparatus of the present invention can be oriented so that the crystal is pulled horizontally, downwardly or at an angle out of the molten zone. The fiber pulling assembly may be enclosed in a gas tight chamber, thereby allowing growth in a controlled atmosphere (e.g., vacuum or an inert gas), though for the synthesis of many oxides the LHPG process can be carried out in air. Typical fiber growth rates range from 0.1 to 10 cm min⁻¹ (1-100 mm min⁻¹) with diameter reductions (i.e., ratio of feed rod diameter to fiber diameter) of approximately three. Such a system can produce fibers in lengths of 20 cm or more of a wide variety of materials. Further, the very high axial temperature gradient in LHPG (typically several hundred degrees C./mm) allows one to grow crystals “off-equilibrium”, which means that a variety of non-congruent compositions can be grown (e.g., having variable stoichiometry, or with the addition of dopants, etc.).

While the steep temperature gradients common to LHPG allow a fast fiber growth rate, this can also lead to severe thermal stresses and cracking when the diameters of the pulled single crystal become larger. Although fibers with diameters as small as 10 μm can generally be grown using existing LHPG methods and apparatus, the most commonly used diameters for investigating the properties of a material are generally in the range 200-1000 μm. This is due to the difficulty in making certain measurements on samples with a smaller diameter and conversely, the difficulty using existing apparatus, of producing crystals of greater diameter. The steep temperature gradients and fast growth rates used during fiber growth, together with the large radiating surface area of the fibers, mean that the crystals cool rapidly after growth compared with a bulk crystal inside a furnace. The fast quenching rates may lead to the suppression of high temperature solid state phase transformations as has been encountered, for example, in the growth of fiber crystals of materials such as BaTiO₃ and ScTaO₄.

Basic considerations, showing the characteristics of fiber growth by the LHPG technique, were discussed by Feigelson (1986). The strains resulting from non-uniform temperature distribution in pulled crystals and other cylindrical bodies have been studied by several authors. It is generally acknowledged to be impossible to pull a crystal in the absence of an axial temperature gradient. If the length of the crystal exceeds its diameter, a radial gradient with a concomitant thermal stress will also exist. The effects of a nonuniform thermal field in floating zone-like crystal growth techniques have been studied in recent years by several authors. One such effect is related to the radial and axial temperature gradients in the growing crystal required to prevent undue thermal stress which has a tendency to crack the material.

The very high temperature gradients imposed by existing LHPG techniques places strict limits on the maximum crystal size which can be grown without cracking. For many refractory oxide materials, the maximum crystal size has a diameter of less than 2 mm. The general equation for the maximum acceptable axial gradient before a crystal of radius R breaks has been established by Brice [Brice, J. C.: J. Cryst. Growth 42 (1977) 427] as:

$${( \frac{d T}{d Z} )}_{max} = {( \frac{4 {ɛ}_{b}}{α {R}^{3 / 2}} ) [ \frac{1}{h} ]}^{1 / 2} ( 1 - \frac{1}{2} hR ) \qquad ( 1 )$$

where:

ε_{b} is the breaking strain of the crystal

h is the cooling constant

α is the thermal expansion coefficient

For smaller crystals (up to about 2 cm in diameter), Equation 1 can be reduced to:

$${( \frac{d T}{d Z} )}_{max} = {( \frac{4 {ɛ}_{b}}{α {R}^{3 / 2}} ) [ \frac{1}{h} ]}^{1 / 2} \qquad ( 2 )$$

Equations 1 and 2 show that the axial gradient is inversely proportional to R^{3/2}. The bigger the radius of the crystal, the smaller is the maximum acceptable axial gradient. Consequently, to grow bigger crystals, the axial gradient during growth must be reduced. The thermal stress can be decreased by limiting the radius of the growing crystal or, as described below, by an appropriate in situ post-growth thermal treatment.

For example, in the case of LiNbO₃ it has been shown [Brice, J. C.: J. Cryst. Growth 42 (1977) 427] that during the growth of a crystal with a radius R, there is a maximum acceptable axial gradient roughly proportional to R^{-1.5} and that to prevent cracking after growth there is a maximum rate of cooling proportional to R⁻². Installation of a post-growth heating system (sometimes termed an afterheater) sometimes facilitates the growth of crystals with larger diameters. Some workers have reported that sometimes increasing the heat loss from the fiber by, for example, carrying out the growth in a gas of higher thermal conductivity than air, can reduce the radial thermal gradients. [U.S. Pat. No. 5,607,506; Phomsakha et al 1997].

Independent of the crystal growth method, it is well known that as crystals get bigger in length and diameter, the intrinsic defects and strain are more likely to increase beyond their mechanical tolerance threshold, causing the crystals to crack. Axial (along the length) and radial (across the diameter) temperature gradients greatly influence cracking. Reducing these gradients is imperative to grow good quality uncracked crystals. In the Czochralski method, an afterheater has been used with success to reduce the axial gradients during crystal growth. It has, however, been claimed [Fejer, Martin M.: Ph.D. thesis, Applied Physics, Stanford Univ., 1986] that an afterheater would exacerbate cracking during the growth of crystal fibers by LHPG as most of the heat loss is radiative.

However, in this regard, only fibers of very small diameters (less than 800 microns) have been considered. For diameters greater than 2.0 mm, the analysis changes. Brice [Brice, J. C.: J. Cryst. Growth 42 (1977) 427] has developed the equations that govern the temperature gradients (radial and axial) in Czochralski growth, although not for LHPG. The Czochralski technique allows one to grow much bigger crystals than are possible with the standard LHPG technique and the equations in the Brice paper do not apply to crystals with diameters of less than about 10 mm. However, the appropriate coefficients for a modification of the Brice equation that governs axial temperature gradients have been determined experimentally for the LHPG technique [Fejer, Martin M.: Ph.D. thesis, Applied Physics, Stanford Univ., 1986; J-C Chen et al, J. Cryst. Growth 208 (2000) 508]. The equation is:

$${( \frac{d T}{d Z} )}_{max} = \frac{A}{{R}^{3 / 2}} \qquad ( 3 )$$

The coefficient A varies with the material to be grown (for example, A=808 for sapphire; and A=240 for c-axis lithium niobate).

Equation 3 suggests that to prevent crystals with diameters greater than about 2 mm from cracking, the afterheater temperature should be set close to the melting point of the material. Prior art proposals to limit thermal stress by applying an in situ post-growth thermal treatment include both resistive afterheaters and optical afterheaters.

[J-C Chen et al, J. Cryst. Growth 208 (2000) 508] used LHPG with a resistive afterheater, consisting of four turns of Nichrome wire, to grow fibers of LiNbO₃ up to 1.7 mm in diameter. They demonstrated that this resistive afterheater could maintain temperature gradients between 600-700° C./mm. Unfortunately, this magnitude of temperature gradient is still far too large to allow growth of crack-free LiNbO₃ crystals in sizes larger than 2.0 mm.

[D. Reyes Ardila et al, Rev. Sci. Ins. 72 (12), (2001) 4415] used an optical afterheater approach. Reyes Ardila et al modified a spherical LHPG focusing mirror to generate two foci separated by 1.0 mm. This bifocal spherical mirror was made by slicing a spherical copper mirror into eight sectors, and displacing alternate sectors by 1.0 mm along the growth direction. The lowered symmetry of the heating beam did not harmfully reduce the heating uniformity in the molten zone. Measured temperature gradients were significantly reduced (to approximately 300° C./mm) relative to standard LHPG. The relative surface areas of the two sets of displaced mirror sectors (approximately 3:1) defined the relative amounts of laser power focused on the melt and on the afterheated region. And the identical figures on the two sets of displaced mirrors generated foci in the molten and afterheated regions with identical shapes. Each of these limitations imposed by the bifocal spherical mirror design reduces the flexibility of the LHPG apparatus to grow materials of different melting points, thermal conductivities, breaking strains and diameters. Reyes Ardila et al grew LiNbO₃ fibers of 1.6-1.7 mm maximum diameter using their bifocal spherical mirror.

Unfortunately, many applications require larger diameter crystals than it has been possible to grow using current LHPG technique, even including the afterheater approaches described above. To the inventors' knowledge, the upper limits for the afterheater approaches described above are less than 1.7 mm diameter for lithium niobate and less than 2 mm diameter for sapphire.

### SUMMARY OF THE INVENTION

The present invention overcomes the limitations of the prior art by providing a flexible post-growth optical afterheater system. This optical afterheater system includes an appropriate choice of optical heat source for the single crystal material to be heated, a power adjustment module for controlling the optical power heating the crystal, and suitable focusing optics to focus the heating beam onto the crystal. The heat source may be a laser of appropriate wavelength or an incoherent source of sufficient power. In one embodiment, the power adjustment module is an optical attenuator, either of crossed-polarizer design or of intersecting wire grids. Other examples include variable absorbers and variable reflectors, which transmit an adjustable optical power to the region of interest on the crystal. The focusing optics may be refractive, reflective, or catadioptric, depending on factors such as diameter, cost target, and space available in the crystal growth apparatus. The shape of the power distribution in the focal region(s) preferably is adjustable, so that the temperature gradient in the newly-grown crystal may be adjusted according to the properties of the single crystal. Important properties (both intrinsic and extrinsic) include melting point, thermal conductivity, and diameter.

The power adjustment module adds flexibility by allowing adjustment of the relative power in the molten zone beam compared to the afterheater beam. In addition, the use of adjustable focusing optics (e.g., a zoom beam expander) allows adjustment of the temperature gradient in the afterheater region. This added flexibility enables optimization for a wide variety of materials with different melting points, thermal conductivities, and diameters.

In one approach, a single optical beam is split and used as both the molten zone beam for melting the material and as the afterheater beam for the post-growth annealing function. The molten zone beam and afterheater beam each are preferably circularly symmetric in order to more easily maintain even heating of the crystal. A power adjustment module preferably allows adjustment of the power of the molten zone beam, of the afterheater beam and/or of the power ratios of the two beams. The use of a single optical beam to generate both the molten zone beam and the afterheater beam is advantageous because it can reduce overall cost (e.g., only one source is needed, not two) and complexity (e.g., alignment of two separate sources is not required). Power adjustment allows increased flexibility to accommodate different growth conditions, as well as changes in equipment over time.

In one design, a concentric bifocal mirror is used to divide a single laser beam and focus the resulting molten zone beam and afterheater beam to their corresponding locations on the crystal. The bifocal mirror can be fabricated from a single piece of material using conventional techniques (such as diamond turning), which simplifies fabrication. The bifocal design facilitates the achievement of fast f/#'s, which helps to avoid undue power concentration on the crystal surface, which might result in unwanted melting of the seed crystal by the afterheater.

The inner (afterheater) focus is bounded by the requirement that the afterheater beam not be significantly absorbed by the seed crystal. As a result, the f/# is usually faster (i.e., less than) f/1.0. The outer (molten zone) focus is typically faster than the afterheater focus because its beam sector diameter is appreciably greater than that of the afterheater beam, and the molten zone focal length is longer than the afterheater focal length usually by a distance less than 2 mm. The minimum molten zone f/# is typically determined by practical factors related to mirror fabrication. For example, a mirror faster than f/0.1 is difficult to fabricate and test. Typical focal ratios (i.e., f/#s) for both the afterheater and molten zone foci are in the range 0.2-0.5 or more preferably 0.2-0.4.

Power adjustment can be used to adjust the powers of the molten zone beam and/or the afterheater beam and also to adjust the ratio of power between the two beams. This approach can be used to fabricate defect free, high purity single crystals of larger diameter than is generally feasible using existing LHPG apparatus (as far as the inventors are aware). It is especially useful in fabricating larger diameter single crystals of high melting point materials.

Other aspects of the invention include components (such as the concentric bifocal mirror) and methods corresponding to the devices and systems described above.

### BRIEF DESCRIPTION OF THE DRAWINGS

The invention has other advantages and features which will be more readily apparent from the following detailed description of the invention and the appended claims, when taken in conjunction with the accompanying drawings, in which:

FIG. 1 is a block diagram of one embodiment of an optical afterheater system according to the present invention.

The figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION OF THE PREFERRED EMBODIMENTS

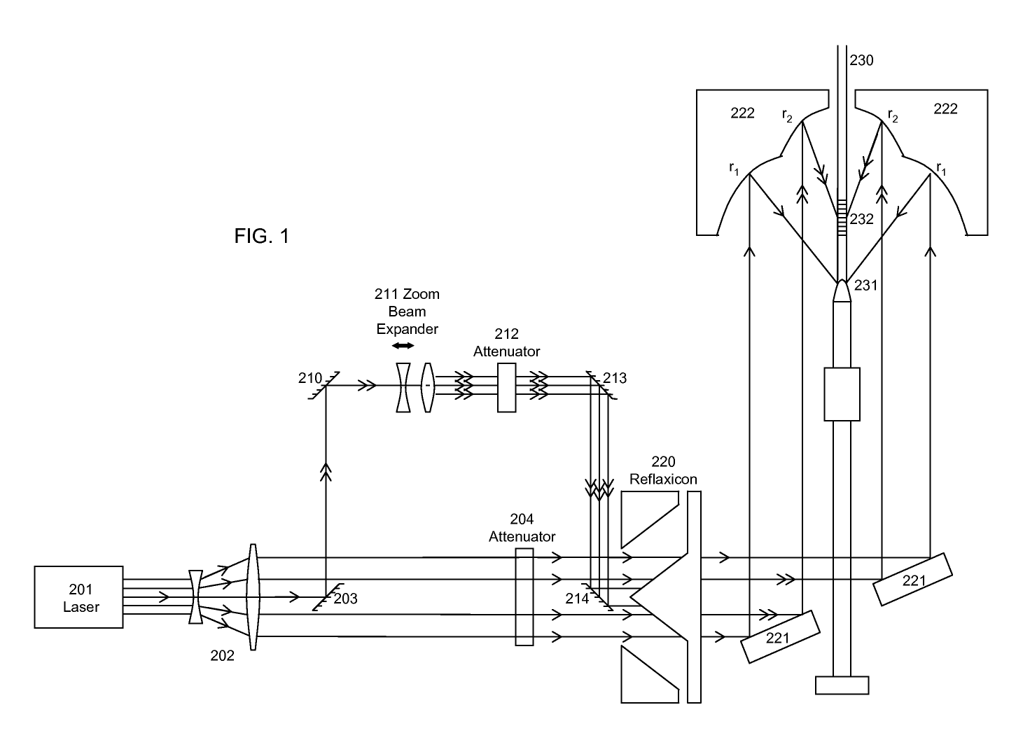

FIG. 1 depicts an optical afterheater system according to the present invention. The system includes an appropriate choice of optical heat source for the single crystal material to be heated, a power adjustment module for controlling the optical power heating the crystal, and suitable focusing optics to focus the heating beam onto the crystal.

Fejer [Fejer, Martin M.: Ph.D. thesis, Applied Physics, Stanford Univ., 1986] has considered the factors which influence the choice of laser wavelength used as a heat source in LHPG. These factors include both material properties governing the interaction of the laser with the crystal, and the availability of reliable lasers of the desired wavelength and power.

For efficient heating, the wavelength illuminating the molten zone preferably should be completely absorbed. In the absence of a reflector, any transmitted (i.e., not absorbed) light is wasted. For relatively small fiber crystals (under 1 mm diameter), this constrains the melt absorption coefficient at the laser wavelength to exceed 1 cm⁻¹. Many oxide crystals exceed this threshold throughout the infrared.

To avoid excessive surface heating, which causes undesirable excessive convection in the melt, the heating wavelength should be transmitted through at least 20% of the crystal's radius, r. This places a maximum absorption limit on the crystal of 50/r. For example, the desired maximum absorptivity of a 2.0 mm diameter crystal (for which r=0.1 cm) is 500 cm⁻¹. Many target oxide crystals exceed this threshold as well throughout much of the infrared, but choosing a heat source that limits convection in the melt remains advantageous.

Commercially available laser sources in the near-to mid infrared wavelength region with high multiwatt power include Yb fiber (1.07 μm); CO (5 μm); and CO₂ (9-11 μm). Virtually all existing LHPG systems have utilized CO₂ lasers because they are relatively low cost, costing on the order of $100 per watt of laser power. Recent improvements in high-power diode pump lasers for Yb fiber lasers have brought this technology closer to cost-competition with CO₂ lasers. Current prices for Yb fiber lasers of appropriate powers are now $300 per watt, and continue to fall rapidly with steady improvements in the 808 nm diode lasers used to pump Yb fiber lasers. Moreover, the Yb fiber laser's shorter lasing wavelength (1 μm vs. 10 μm) offers an advantage as a heat source for growing larger crystals of some materials using LHPG. Many oxide materials of interest transmit 1 μm radiation farther into the crystal or into the melt than 10 μm radiation. For a laser heat source for melting the material, the greater transmission of Yb fiber laser radiation into the melt reduces the thermal convection due to surface melting. For an optical afterheater, the greater transmission into the single crystal allows finer control of the thermal profile of the afterheated zone of the solidified crystal.

For the example system shown in FIG. 1, a CO₂ laser 201 is chosen as the optical heating source. Referring again to FIG. 1, the collimated linearly-polarized Gaussian beam of the CO₂ laser 201 is magnified by a beam expander 202, focused to maintain a collimated expanded beam. Although 202 is shown as a Keplerian beam expander in the figure, a beam expander of Gaussian (inverting) design could alternatively be employed. The central portion of the magnified laser beam is deflected by turning mirrors 203 and 210. This central portion is termed henceforth the afterheater beam, because it is focused on a portion of the single crystalline rod 230 to heat it soon after it freezes.

The afterheater beam passes through a zoom beam expander 211 of unity magnification. The Keplerian design shown for zoom beam expander 211 consists of a diverging lens of focal length −f and a converging lens of focal length +f, separated by a distance of approximately f which can be adjusted finely, e.g. using a precision translation stage. Such adjustments in the inter-lens spacing result in an afterheater beam which can be varied from slightly divergent through collimated to slightly convergent. The afterheater beam propagates from the zoom beam expander 211 through attenuator 212, which reduces its power by a controlled amount. After passing through the attenuator 212, the afterheater beam reflects off mirrors 213 and 214, and is recombined into a circular beam.

The annular beam that remains after turning mirror 203 has picked off its central portion is termed the molten zone beam. The molten zone beam propagates through attenuator 204, which reduces its power by a controlled amount. After passing through the attenuator 204, the annular molten zone beam is recombined with the circular afterheater beam by mirror 214.

The circular recombined beam reflects off the two conical surfaces of the reflaxicon 220, yielding an annular beam of larger diameter (this reflection is not quite shown accurately in FIG. 1, in order to simplify the drawing). The inner portion of the annular beam is the afterheater beam, while the outer portion of the annular beam is the molten zone beam. The annular beam emerging from the reflaxicon 220 reflects off the elliptical flat mirror 221 to the paraboloidal mirror 222. The outer portion of the annular beam impinges on the section with radius r₁ of the paraboloid mirror 222, which focuses it on the rod to be melted at the molten zone 231. The power delivered to the molten zone 231 can be adjusted using a combination of the laser power and attenuator 204.

The inner portion of the annular beam impinges on the section with radius r₂ of the paraboloid mirror 222, which focuses it on the single crystalline rod 230 just above the molten zone 231 to create the afterheater zone 232. The power of the afterheater beam can be adjusted using attenuator 212, and the length of the afterheater zone 232 can be adjusted by defocusing zoom beam expander 211. By adjusting the power of the afterheater beam and the length of the afterheater zone 232, one may obtain the desired temperature gradient in the afterheater zone 232. The local temperature of sections of the growing crystal 230 can be monitored by an optical pyrometer. Depending on the nature of the material to be grown as a single crystal, different temperature gradient profiles may be required. The temperature gradients can be adjusted by changing the power density of the laser beam in the afterheater zone 232. The power density can be varied by changing the length of the afterheater zone 232, by focusing or defocusing the zoom beam expander 211. The length of the afterheater zone 232 can thus be adjusted over a useful range of 2-10 mm length (in this example) using the zoom beam expander 211.

The optical afterheater system shown in FIG. 1 can be operated as follows. In a typical LHPG growth (i.e., no afterheater), the laser beam is turned on from the very beginning of the growth. The ceramic feed rod is brought in the focal zone, and the power of the laser is increased until the tip of the rod is melted. The power of the laser is then adjusted until the molten zone has the desired shape. The seed is then dipped in the molten zone and the laser power adjusted again so that the molten zone does not freeze. When a satisfactory shape is achieved, the crystal is pulled.

With an afterheater, the growth procedure is modified. The afterheater zone 232 is tuned for the particular material being grown by using the zoom beam expander 211 to adjust the length of the afterheater zone 232, and the attenuator 212 to adjust the power inside the afterheater zone 232.

The afterheater zone and hence the position of the focal point of the afterheater beam are a function of the melting temperature of the material.

Ta=Tm−T (4)

where Ta is the afterheater zone temperature and Tm is the melting point. The parameter T is typically set at around 200° C., but can vary with the intrinsic properties of the material (phase transitions, conductivity, etc.).

As rather high axial gradients are needed to ensure good seeding of the crystal, the afterheater preferably should be turned on only after the crystal starts growing. The time to turn on the afterheater will depend on the position of the afterheater zone, defined in Equation 4, and also on the thermal conductivity of the material. In this embodiment, the afterheater temperature may be ramped where appropriate.

The concentric bifocal focusing mirror used for this embodiment is advantageous in that it presents two different focusing zones with different focal radii, r₁ and r₂, instead of only one r as in a conventional LHPG setup. The outer section of the mirror focuses light to a point farther from the mirror to create the molten zone from which the formed crystal is pulled. The power of the light impinging on this outer focusing zone is adjusted (i.e., increased or decreased) to meet the requirements of the material being grown (melting point, diameter, thermal conductivity, etc.) and maintain stable growth. The power of this molten zone beam may be increased by increasing the laser power. The power of the molten zone beam may be decreased either by decreasing the laser power, or by adjusting the attenuator 204.

The inner section of the mirror focuses light along a line closer to the mirror, and heats the newly-grown single crystal. The power of the light impinging on this inner focusing zone is controlled using attenuator 212 to limit the thermal gradient in the crystal. Control over the length of the afterheater zone, which is connected to the thermal gradient of the crystal, is exerted by focusing or defocusing the zoom beam expander 211. Due to the independent control of the power to each zone, materials with widely different melting points, thermal conductivities, and breaking strains can be grown with this apparatus in larger diameters than has heretofore been possible using the LHPG technique.

The dual-zone mirror of the present invention can be manufactured using known methods, e.g., single-point diamond turning. Suitable mirror materials include appropriate alloys of either copper or aluminum. A gold coating may be applied to protect the mirror surface against corrosion and to increase its reflectivity in the infrared.

Referring to FIG. 1, the focal lengths f₁ and f₂, respectively for beam 1 and beam 2 are defined by the radii r₁ and r₂. The outer portion of the mirror, which creates the molten zone focus, requires a paraboloidal figure to maintain a near-point focus to melt the source rod. For a parabolic mirror with focal length f₁, the equation of the parabola whose revolution about the optical axis yields the paraboloidal surface of revolution is:

$$y = \frac{{x}^{2}}{4 {f}_{1}} \qquad ( 5 )$$

The inner portion of the mirror, which creates the afterheater zone, may have a spherical or paraboloidal figure, for example. A spherical surface with its inherent spherical aberration generates a line focus even with collimated light impinging on it. For a spherical mirror sector with radius of curvature r₂, the focal length f₂=r₂/2. Alternatively, the inner portion of the mirror may have a paraboloidal figure, since the off-axis rays introduced by a defocused beam expander will be reflected by a paraboloidal mirror onto a line focus. The length of the line focus may be adjusted (i.e., made longer or shorter) by defocusing the zoom beam expander 211. This defocusing affords one means for varying the thermal gradient of the crystal in the afterheater zone 232. The power impinging on the crystal in the afterheater zone 232 may be adjusted using the attenuator 212. Adjusting this attenuator 212 affords a second means of varying the thermal gradient of the crystal in the afterheater zone 232.

The power out of either attenuator may be adjusted by changing the orientation of the linear polarizer inside the attenuator. For this design of attenuator, the incoming laser beam is linearly polarized. Use of a wire-grid attenuator relaxes the requirement for linear polarization of the incoming beam. The attenuator is adjusted in such a manner that the temperature of the afterheater zone be kept about 200° C. lower than the melting temperature of the molten zone to thereby significantly reduce the axial gradient. Thermal axial gradients of below 400 degrees C./mm are preferred to grow larger diameter lithium niobate crystals.

Although the detailed description contains many specifics, these should not be construed as limiting the scope of the invention but merely as illustrating different examples and aspects of the invention. It should be appreciated that the scope of the invention includes other embodiments not discussed in detail above. Various other modifications, changes and variations which will be apparent to those skilled in the art may be made in the arrangement, operation and details of the method and apparatus of the present invention disclosed herein without departing from the spirit and scope of the invention as defined in the appended claims. Therefore, the scope of the invention should be determined by the appended claims and their legal equivalents.

What is claimed is:

1. A laser heated pedestal growth optical afterheater system for growing a single crystal rod, comprising:
a device for growing a single crystal rod from a feed material via laser heated pedestal growth;
a laser that generates a first laser beam; and
a concentric bifocal mirror positioned optically downstream of the first laser beam, the first laser beam transformed into a molten zone beam and an afterheater beam, the bifocal mirror including a first circularly symmetric focusing zone and a second circularly symmetric focusing zone, the first focusing zone directing the molten zone beam to melt the feed material at a molten zone interface to the single crystal rod, and the second focusing zone directing the afterheater beam to an afterheater region of the single crystal rod.

2. The system of claim 1 further comprising:
a first mirror positioned optically between the laser and the concentric bifocal mirror, the first mirror deflecting a central portion of the first laser beam to thereby form a circular laser beam and an annular laser beam, one of the circular laser beam and the annular laser beam being the molten zone beam and the other being the afterheater beam; and
a second mirror that optically realigns the molten zone beam and the afterheater beam.

3. The system of claim 2 wherein the second focusing zone focuses the afterheater beam along a line lying along a crystal growth axis in the afterheater region of the single crystal rod.

4. The system of claim 2 further comprising:
an optical attenuator positioned optically between the first mirror and the second mirror in an optical path of the afterheater beam.

5. The system of claim 2 further comprising:
an optical attenuator positioned optically between the first mirror and the second mirror in an optical path of the molten zone beam.

6. The system of claim 2 further comprising:
a reflective axicon positioned optically between the second mirror and the concentric bifocal mirror, the reflective axicon transforming the realigned molten zone beam and afterheater beam into a substantially annular beam; and
an elliptical flat mirror with a central hole, the feed material and/or single crystal rod positioned through the central hole, the elliptical flat mirror positioned optically between the reflective axicon and the concentric bifocal mirror to direct the substantially annular beam to the concentric bifocal mirror.

7. The system of claim 6 further comprising:
a housing with a controlled atmosphere enclosing the molten zone interface and at least a portion of the single crystal rod and the feed material, the housing having a window positioned to admit the substantially annular beam.

8. The system of claim 2 wherein the circular laser beam is the afterheater beam and the annular laser beam is the molten zone beam.

9. The system of claim 8 further comprising:
a zoom beam expander positioned optically between the first mirror and the second mirror in an optical path of the afterheater beam.

10. The system of claim 1 wherein the first circularly symmetric focusing zone of the concentric bifocal mirror is a paraboloid mirror in shape and the second circularly symmetric focusing zone of the concentric bifocal mirror is also a paraboloid mirror in shape.

11. The system of claim 1 wherein each of the circularly symmetric focusing zones has an f/# in the range 0.2 to 0.5.

12. The system of claim 1 wherein the laser is a mid-infrared laser.

13. The system of claim 1 wherein the laser is a CO₂ mid-infrared laser.

14. The system of claim 1 wherein the laser is a Yb fiber mid-infrared laser.

15. The system of claim 1 wherein the system is capable of growing a single crystal rod of lithium niobate at least 1.8 mm in diameter.

16. The system of claim 1 wherein the system is capable of growing a single crystal rod of lithium niobate at least 2.0 mm in diameter.

17. The system of claim 1 wherein afterheating in the afterheater region maintains a thermal axial gradient of the single crystal rod to below 400 degrees C./mm.

18. A laser heated pedestal growth optical afterheater system for growing a single crystal rod, comprising:
a device for growing a single crystal rod from a feed material via laser heated pedestal growth;
a laser that generates a first laser beam;
a first mirror that deflects a central portion of the first laser beam to thereby form a circular afterheater beam and an annular molten zone beam;
a second mirror that optically realigns the molten zone beam and the afterheater beam;
a first optical attenuator and zoom beam expander positioned between the first and second mirrors in an optical path of the afterheater beam;
a second optical attenuator positioned between the first and second mirrors in an optical path of the molten zone beam;
a reflective axicon that transforms the realigned molten zone beam and afterheater beam into a substantially annular beam;
an elliptical flat mirror with a central hole, the feed material and/or single crystal rod positioned through the central hole, the elliptical flat mirror directing the substantially annular beam to a direction parallel to the crystal growth axis of the single crystal rod; and
a concentric bifocal mirror including a first circularly symmetric paraboloid mirror and a second circularly symmetric paraboloid mirror, the first paraboloid mirror directing the molten zone beam to melt the feed material at a molten zone interface to the single crystal rod, and the second paraboloid mirror directing the afterheater along a line lying along the crystal growth axis in an afterheater region of the single crystal rod.

19. A laser heated pedestal growth optical afterheater system for growing a single crystal rod, comprising:
a device for growing a single crystal rod from a feed material via laser heated pedestal growth;
a laser that generates a first laser beam;
an optical train that separates the first laser beam into a molten zone beam and an afterheater beam, the optical train further including a power adjustment module positioned in an optical path of the afterheater beam; and
a bifocal mirror positioned to direct the molten zone beam to melt the feed material at a molten zone interface to the single crystal rod, and to direct the afterheater beam to an afterheater region of the single crystal rod, the power adjustment module capable of adjusting an optical power of the afterheater beam and/or a focus of the afterheater beam in the afterheater region.

20. The laser heated pedestal growth optical afterheater system of claim 19 wherein the power adjustment module includes an optical attenuator that adjusts an optical power of the afterheater beam.

21. The laser heated pedestal growth optical afterheater system of claim 19 wherein the power adjustment module includes an optical zoom beam expander that adjusts a focus of the afterheater beam in the afterheater region.
